(19) United States
(12) Patent Application Publication
(10) Pub. No.: US 2023/0067686 A1
(43) Pub. Date: Mar. 2, 2023

(54) Universal Pin Production Support (UPPS)

(71) Applicants: Matthew Miller Reggio, Dover, NH (US); Owen Bruce Hilton, New York, NY (US)

(72) Inventors: Matthew Miller Reggio, Dover, NH (US); Owen Bruce Hilton, New York, NY (US)

(21) Appl. No.: 17/889,534

(22) Filed: Aug. 17, 2022

Related U.S. Application Data
(60) Provisional application No. 63/236,384, filed on Aug. 24, 2021.

(51) Int. Cl. H05K 3/00

(52) U.S. Cl. CPC H05K 3/007; H05K 3/0008; H05K 2203/0147

(57) ABSTRACT

A universal pin production support device provides a resettable surface mount carrier that eliminates the need for single assembly tooling. The design of the UPPS allows for it to be custom set to fix and support each specific circuit board or assembly.

### CROSS REFERENCE TO RELATED APPLICATION

The present application claims priority to and the benefit of U.S. patent application Ser. No. 63/236,384, filed Aug. 24, 2021, which is hereby incorporated by reference in its entirety.

### TECHNICAL FIELD

The present disclosure is directed to surface mount soldering circuit board technology and more particularly, relates to a universal pin production support (UPPS) that is configured as a resettable surface mount carrier to eliminate the need for single assembly tooling. The design of the UPPS allows for it to be custom set to fix and support each specific circuit board or assembly.

### BACKGROUND

As is known in the industry, surface mount process carriers are engineered to precisely align and hold circuit boards from start to finish in the assembly process. These carriers are typically made of high-temperature semi-conductive composite materials, and are used from start to finish in the assembly process. Currently, surface mount carriers are constructed and used specific to a given circuit board. This practice thus requires that each circuit board has its own surface mount carrier and therefore, this practice is time consuming and adds costs and complexity. More specifically, surface mount soldering circuit boards poses a multitude of challenges, each specific to a certain assembly. The geometry, components and design of an assembly require specific tooling, fixtures and carriers to successfully dispense solder, pick and place components, and reflow.

As the demand for circuit boards increases, it is necessary that a process becomes more streamlined, and the tools, such as the surface mount carrier, become more universal and thus be reusable and adjustable to each specific need.

### SUMMARY

The disclosed universal pin production support device provides a resettable surface mount carrier that eliminates the need for single assembly tooling. The design of the UPPS allows for it to be custom set to fix and support each specific circuit board or assembly.

As described herein and illustrated in the figures, the UPPS is a tool designed to increase the process efficiency and assembly time needed to complete a surface mount circuit board. By utilizing the design of the UPPS, there is a decrease in time spent from a bare circuit board to a complete circuit board by eliminating tooling lead times and shortening tooling changeover times.

### BRIEF DESCRIPTION OF THE DRAWING FIGURES

FIG. 1 is a top plan view of a UPPS according to one exemplary embodiment;

FIG. 2 is a bottom plan view thereof;

FIG. 3 is a bottom plan view showing various actions and movements of parts of the UPPS;

FIG. 4A is a side elevation view thereof;

FIG. 4B is cross-sectional view taken along the line A-A of FIG. 4A;

FIG. 4C is an enlarged sectional view of a portion of the UPPS;

FIG. 5A is an exploded bottom view;

FIG. 5B is an exploded side view;

FIG. 6 is a front elevation view thereof;

FIG. 7 illustrates one exemplary pin; and

FIG. 8 illustrates one exemplary CAM knob.

### DETAILED DESCRIPTION OF CERTAIN EMBODIMENTS

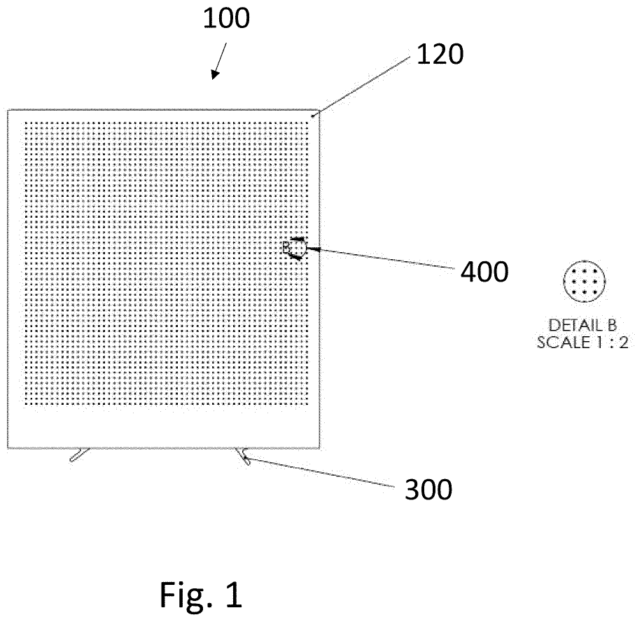

Now referring to FIGS. 1-8, a universal pin production support (UPPS) 100 is illustrated and is configured as a resettable surface mount carrier to eliminate the need for single assembly tooling. As discussed herein, the design of the UPPS 100 allows for it to be custom set to fix and support each specific circuit board or assembly.

Main Housing 110

The UPPS 100 includes a main housing 110 that is defined by a top wall or top plate 120 and a bottom wall or bottom plate 130 that is spaced therefrom so as to define an interior space therebetween. In its assembled state, the top plate 120 and the bottom plate 130 are parallel to one another. The thicknesses of the top plate 120 and the bottom plate 130 can be the same as shown or they can be different.

The main housing 110 can be formed to have any number of different sizes and shapes based on the intended application of the UPPS 100. The main housing 110 can have a polygonal shape or can be non-polygonal in shape. For example, the main housing 110 can have a square or rectangular shape.

The top plate 120 has a plurality of first through holes 122 formed therein. As the name indicates, each first through hole 122 passes completely through the top plate 120. The first through holes 122 are formed perpendicular to the first and second opposing faces of the top plate 120. When assembled, the first face comprises a first outward face of the UPPS 100. The sizes (diameters) of the first through holes 122 are preferably the same and in one embodiment, the first through holes 122 comprise circular shaped holes that have first diameters. The first through holes 122 can be and are preferably formed in a uniform pattern in that the spacing between the first through holes 122 is the same. The first through holes 122 can thus be laid out in a regular grid format. Alternatively, the first through holes 122 can be laid out in a non-uniform manner.

In view of the foregoing, the top plate 120 can be considered to be a perforated plate.

In contrast to the perforated top plate 120, the bottom plate 130 is a solid structure that is devoid of the first through holes 122 or other hole structures.

The top plate 120 can be formed on one or more materials and the bottom plate 130 can be formed of the same material or materials or it can be formed of a different material or materials.

Intermediate (Shear) Plate 200

The UPPS 100 also includes an intermediate plate 200 that can be considered to be a shearing plate as described herein. The intermediate plate 200 is configured to received into and move laterally within the interior space that is defined between the top plate 120 and the bottom plate 130. When the main housing 110 is assembled, the intermediate plate 200 is in contact with both the inner face of the top plate 120 and the inner face of the bottom plate 130; however, as mentioned, the intermediate plate 200 is not fixed to either of the top plate 120 and the bottom plate 130 and therefore, it can slidingly move relative to both plates 120, 130.

The intermediate plate 200 does have planar surfaces that seat against the planer inner faces of the top plate 120 and the bottom plate 130. Like the top plate 120, the intermediate plate 200 is a perforated structure in that it includes second through holes 202. As the name indicates, each second through hole 202 passes completely through the intermediate plate 200. The second through holes 202 are formed perpendicular to the first and second opposing faces of the intermediate plate 200. The sizes (diameters) of the second through holes 202 are preferably the same and in one embodiment, the second through holes 202 comprise circular shaped holes that have second diameters. The second diameters are greater than the first diameters (of the first through holes 122) as described below.

The second through holes 202 can be and are preferably formed in a uniform pattern in that the spacing between the second through holes 202 is the same. Like the first through holes 122, the second through holes 202 can be laid out in a regular grid format. The pattern of the first through holes 122 and the second through holes 202 is such that when assembled, at least some of these holes 122, 202 overlap one another (i.e., they are in registration with one another).

Actuator 300

The UPPS 100 further includes one or more actuators 300 that each configured to laterally displace the intermediate plate 200 relative to the top plate 120 and the bottom plate 130. In other words, each actuator 300 is configured such that when operated (manipulated), the actuator 300 applies a force to the intermediate plate 200 to move the intermediate plate 200 in the lateral direction between the top plate 120 and the bottom plate 130. The actuator 300 is also configured so as to allow the intermediate plate 200 to be locked in the laterally moved position subsequent to the actuator 300 acting of the intermediate plate 200.

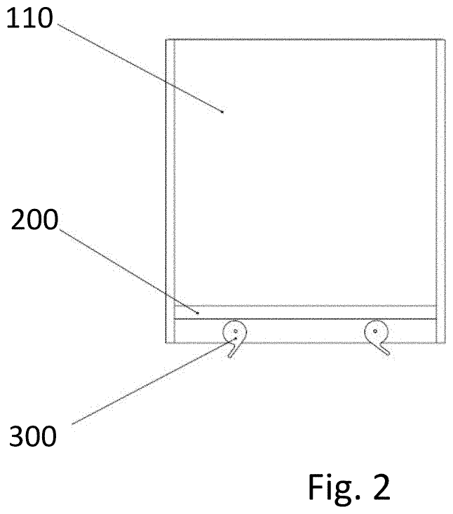

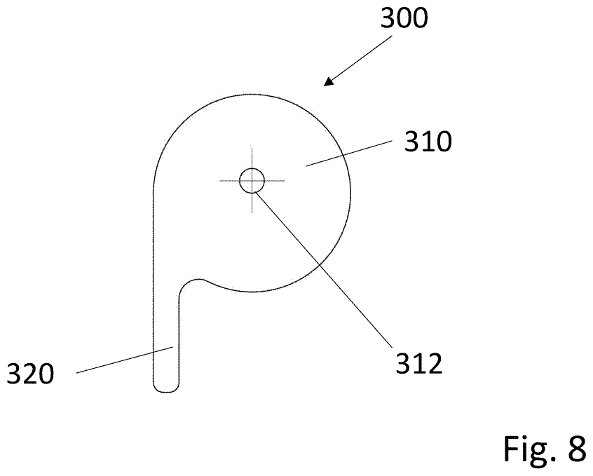

As best shown in FIGS. 2 and 8, the actuator 300 has an eccentric body 310 that is generally circular in shape and has an extension or handle 320 that extends radially outward from the eccentric body 310. The eccentric body 310 has an off centered mounting hole 312 thus giving it eccentric properties. The off centered mounting hole 312 defines a pivot or rotation axis of the actuator 300 with the actuator 300 being coupled to the main housing 110. More particularly, the actuator 300 is disposed within the interior space between the top plate 120 and the bottom plate 130. The handle 320 is accessible along one side of the main housing 110 to allow the operator to access and manipulate the handle 320 to cause rotation of the actuator 300.

As a result of this property, spinning the actuator 300 about the off centered mounting hole 312 will have a varying radius with respect to its radial location. Given its location within the hollow interior space adjacent the intermediate plate 200 applies a force on the intermediate (shear) plate 200 inside the main housing 110.

Each actuator 300 can be considered to be a CAM knob. The illustrated UPPS 100 has two actuators 300 that are spaced apart from one another. For example, one actuator 300 can be located along one half of one side wall of the intermediate plate 200, while the other actuator 300 can be located along the other half of the one side wall.

It will therefore be appreciated that rotation of the actuators 300 causes the eccentric body 310 to come into contact with the one side wall of the intermediate plate 200 and urge the intermediate plate 200 in the lateral direction within the interior space since the intermediate plate 200 is not fixedly attached to either the top plate 120 or the bottom plate 130.

Support Pins 400

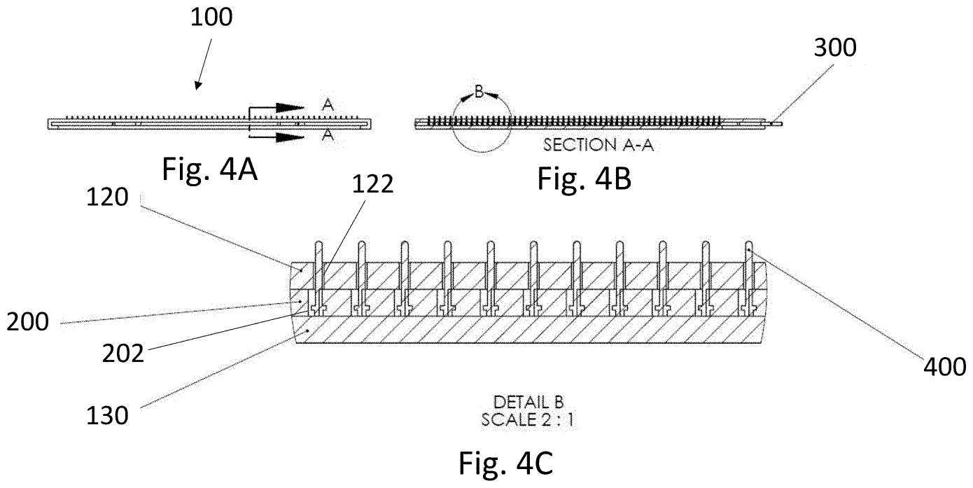

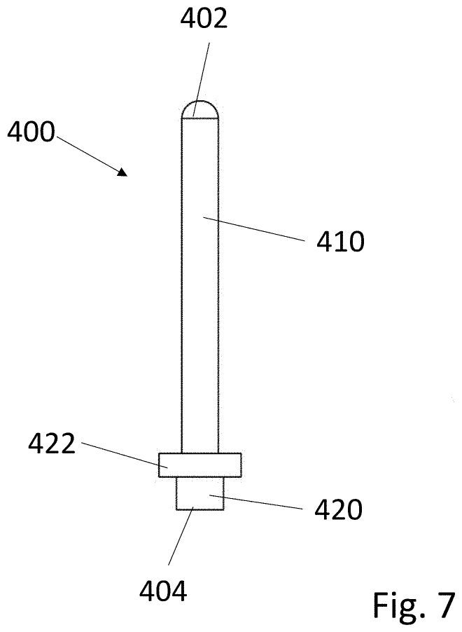

FIGS. 4C and 7 illustrate pins 400 that also form part of the UPPS 100. The pin 400 is an elongated structure that has an elongated shaft 410 that terminates in a distal end 402 and a head 420 located at or near a proximal end 404. As shown, the shaft 410 has a first width (first diameter) and the head 420 is enlarged relative to the shaft 410 and has a second width (second diameter) that is greater than the first width. The shaft 410 is configured to pass through the first through hole 122, while the head 420 cannot pass through the first through hole 122 but can travel within the second through hole 202. The length of the pin 400 is selected such that it is greater than the combined heights of the top plate 120 and the bottom plate 130.

The head 420 has a flange portion 422 that extends radially outward.

The distal end 402 can be a rounded end.

Assembly of the UPPS 100

The UPPS 100 is assembled by disposing the top plate 120 and the intermediate plate 200 together so that the two plates 120, 200 are in contact with one another and the through holes 122, 202 are axially aligned. This combined structure can then be inverted so that the intermediate plate 200 is on top of the top plate 120.

The pins 400 are then inserted into the second through holes 202 by first inserting the shafts 410 into the second through holes 202 and then by gravity allowing the pins 400 to fall downward such that the shafts 410 pass completely though the first through holes 122 of the top plate 120, while the heads 420 travel into the second through holes 202 but cannot enter into the first through holes 122 and thus, the heads 420 seat against the face (inner surface) of the top plate 120.

Next the bottom plate 130 is then joined to this combined structure and more particularly, the bottom plate 130 is coupled to the top plate 120 to form the assembled main housing 110. Any number of techniques can be used to join the bottom plate 130 to the top plate 120 such as the use of adhesives (glue) or the use of fasteners. As mentioned, the intermediate plate 200 can move laterally between the top plate 120 and the bottom plate 130 even after the attaching of the bottom plate 130 to the top plate 120. For example, the plates 120, 130 can be attached along their peripheral edges.

In this assembled state, the pins 400 have a degree of vertical movement that is defined by the movement of the head 420 within the second through hole 202. In other words, the pin 400 can move between a first position in which the head 420 contacts the top plate 120 and a second position in which the head 420 contacts the bottom plate 130. The heads 420 (caps) on the end of the pins 400 thus provide a max protrusion length from the top of the housing 110, while the bottom plate 130 of the housing 110 provides a minimum protrusion length. This eliminates the chance of pins 400 falling out once the housing 110 is assembled.

In this inverted position, the UPPS 100 is then positioned over a printed circuit board (PCB) (not shown) having a given shape and size. The assembled UPPS 100 is then located into contact with the PCB resulting in the PCB contacting select pins 400 resulting in these select pins 400 being depressed (in the inverted position of the UPPS 100, the pins 400 are pushed upward toward the bottom plate 130). It will be appreciated that the pins 100 surrounding the PCB are not contacted by the PCB and thus are not depressed. The net result is that the face of the PCB is coplanar with the distal ends 402 of those pins 400 that are not contacted and not depressed by the PCB.

Next, the one or more actuators 300 are operated to cause lateral movement of the intermediate plate 200 within the interior space between the top and bottom plates 120, 130. The intermediate plate 200 thus applies a shear force to the pins 400. This shear force allows the pins 400 to be locked at certain heights. For example, those depressed pins 400 are locked in the depressed position (first height), while those pins 400 not contacted by the PCB are locked in the extended position (second height). Since the pins 400 surrounding the PCB contact the peripheral edges of the PCB the locking of these pins 400 effectively grasps and holds the PCB in the UPPS 100 after the intermediate plate 200 is laterally moved under action of the one or more actuators 300. The actuator handle, due to its off center fixturing point, has a varying radius depending on its angular position. To ensure the shear plate will not revert back to its starting position, the actuator knobs will be turned past angular position of maximum radius. The handle portion of the actuator knob will act as a stopper once the actuator knobs are turned past the point of maximum radius. This configuration will maintain an angular position where the varying radius is sufficient to apply a horizontal shear force.

Once the PCB is locked in place, the entire assembly can be inverted back over so that the bottom plate 130 assumes its bottom position.

It will be appreciated that the intermediate (shear) plate 200 allows for the pins 400 to lock at a set protrusion length from the top of the housing 110. The actuators 300 (cam knobs) attached to the main housing 100 apply a horizontal shear force to allow for this locking of the pins 400. In other words, spinning the CAM knobs and applying the horizontal pressure sets the pins 400 at the exact protrusion length from the top of the housing 100, allowing for a set surface contour of pins. This provides the outline for the blank circuit board to be inserted. Once the circuit board is inserted into the outline, it can be fed onto a surface mount line for pick and place and reflow. The system keeps the circuit board at an exact fixed position to minimize error and allow for a repeatable alignment process of components. This will allow for a uniform deposition of solder paste and prevent shorting or misaligned components.

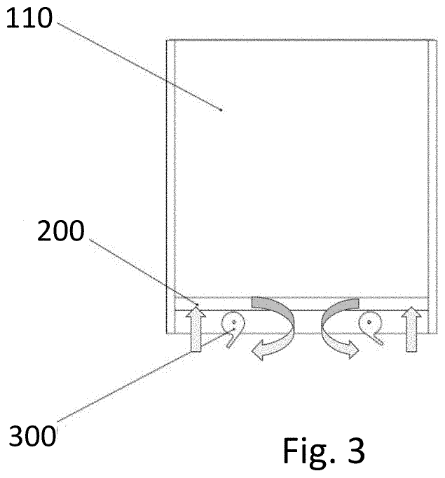

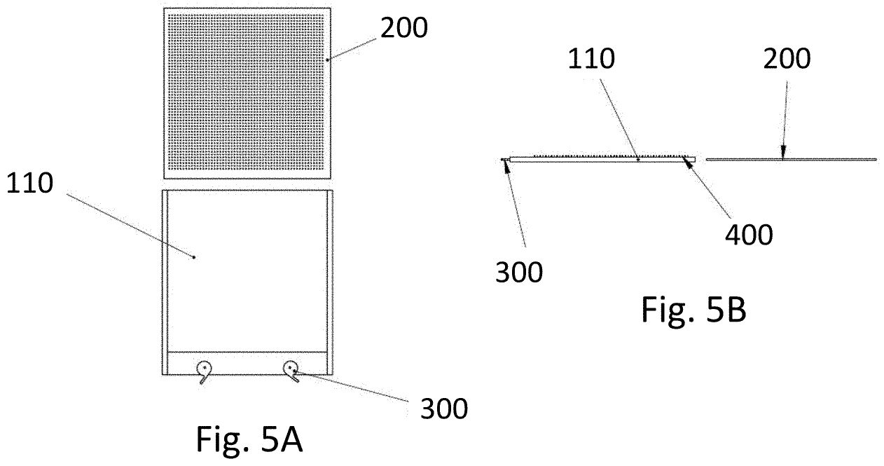

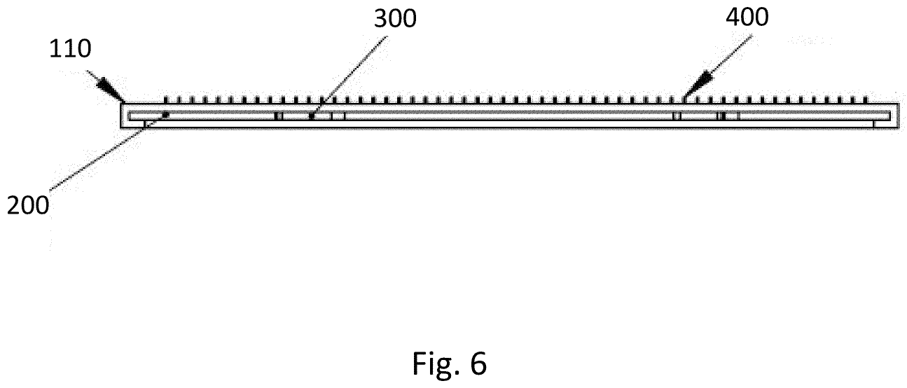

As previously discussed, detail B of FIG. 1 shows a magnified view of the pins 400 extruding from the top face of the housing 110. FIG. 3 shows the action of the device 100. When the CAM knobs 300 are rotated, a horizontal (lateral) force is applied to the shear plate 200 within the main housing 110. FIGS. 4A-C illustrates some of the inner workings of the device. Cross section view A-A of FIG. 4B shows the inside of the device when sectioned lengthwise from front to back. Detail B of FIG. 4C shows a 2:1 scale view of this cross section. From this view, it can be seen that applying a horizontal force on the shear plate (right to left by way of turning the CAM knobs) creates a shear force on the pins. This shear force allows the pins to be locked at a certain height. It can also be seen in Detail B that the pins can move vertically prior to the shear force being applied. FIGS. 5A and 5B depict the exploded view of the device. It can be seen here how the shear plate (2) fits inside the center of the housing (1). FIG. 6 shows the front side view of the device. It can be seen how the shear plate (2) fits inside of the recess of the housing (1). The pins (4) can also be seen protruding through holes in the top of the top of the housing. FIG. 7 shows a close up view of the pin (4). The base of the pin has a head which prohibits it from falling out of the housing once it is inserted into the housing. FIG. 8 shows the CAM knob. It can be seen in this figure that the mounting hole on the CAM knob (3) is not centered. Spinning the CAM knob about the mounting hole will then have a varying radius with respect to its radial orientation. Thus, rotating the CAM knob (3) about the mounting hole, will apply a force on the shear plate (2) inside the housing (1).

Specifics on Materials:

The main housing 110 (top plate 120 and bottom plate 130), and the shear plate 200 are made of a temperature and corrosion resistant composite material or other material. The materials used must hold up to temperatures in excess of 260 C. The cam knobs 300 and the support pins 400 are to be made of a metallic, corrosion resistant material or other material. Having pins that will not wick to solder is imperative for the device to operate correctly. All materials must also resist the corrosiveness of solder flux.

The present UPPS 100 is an improvement to the current process of single assembly fixturing. It is resettable, and therefore, reusable. This eliminates tooling lead times and setup time. It is also a one time cost opposed to paying for tooling for each individual assembly while still providing a consistent, reliable fixture.

It is to be understood that like numerals in the drawings represent like elements through the several figures, and that not all components and/or steps described and illustrated with reference to the figures are required for all embodiments or arrangements.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The subject matter described above is provided by way of illustration only and should not be construed as limiting. Various modifications and changes can be made to the subject matter described herein without following the example embodiments and applications illustrated and described, and without departing from the true spirit and scope of the present invention, which is set forth in the following claims.

What is claimed is:

1. A universal pin production support (UPPS) that acts as a resettable surface mount carrier for fixing and supporting a printed circuit board comprising:
a main housing having a top plate and a bottom plate that is spaced from the top plate,
wherein the top plate has a plurality of first through holes formed therein;
an intermediate plate that is disposed between and can move laterally relative to the top plate and the bottom plate; the intermediate plate having a plurality of second through holes formed therein, the first and second through holes being axially aligned relative to one another;
a plurality of support pins, each support pin having an elongated shaft and a head that is enlarged relative to the elongated shaft, the elongated shaft passing through one first through hole, while the head being sized only for reception in the second through hole aligned with the one first through hole but not the aligned first through hole;
at least one actuator for applying a shear force to the intermediate plate resulting in lateral movement of the intermediate plate causing the plurality of support pins to be set so that the plurality of support pins protrude select distances from an outer surface of the top plate allowing for a set surface contour of the plurality of support pins.

2. The universal pin production support of claim 1, wherein the bottom plate comprises a solid plate devoid of holes.

3. The universal pin production support of claim 1, wherein each second through holes has a greater width than each first through hole.

4. The universal pin production support of claim 1, wherein a height of each support pin is greater than a combined thickness of the top plate and the intermediate plate.

5. The universal pin production support of claim 1, wherein the actuator comprises a CAM knob that is rotatably coupled to the main housing and configured to drive the intermediate plate in a lateral direction.

6. The universal pin production support of claim 5, wherein the CAM knob is eccentrically mounted to the main housing.

7. The universal pin production support of claim 6, wherein the CAM knob has an eccentric body that includes an off-centered mounting hole such that rotation of the CAM knob about the off-centered mounting hole has a varying radius with respect to radial orientation.

8. The universal pin production support of claim 7, wherein the CAM knob includes a handle that extends tangentially outward from the eccentric body.

9. The universal pin production support of claim 5, wherein there are a pair of CAM knobs that are disposed along one side of the main housing.

10. The universal pin production support of claim 7, wherein the eccentric body is disposed between the top plate and the bottom plate.

11. The universal pin production support of claim 1, wherein the top plate and the bottom plate are fixedly attached to one another.

12. The universal pin production support of claim 11, wherein the top plate and the bottom plate are attached to one another with an adhesive or with fasteners.

13. The universal pin production support of claim 1, wherein the plurality of support pins are arranged in a grid format with uniform spacing.

14. A method for fixing and supporting a printed circuit board or assembly in a customizable manner comprising the steps of:
providing a universal pin production support (UPPS) that acts as a resettable surface mount carrier for fixing and supporting the printed circuit board or assembly, the UPPS including a main housing with a plurality of support pins contained at least partially within the main housing, the plurality of support pins configured to move away from and toward a first face of the main housing;
inverting the UPPS such that the first face is positioned above the circuit board or assembly, whereby the inversion of the UPPS automatically causes the plurality of support pins to move to fully extended positions;
lowering the inverted UPPS into contact with the printed circuit board or assembly to causing at least some of the plurality of support pins that contact the printed circuit board or assembly to retract within the main housing with at least some of the plurality of support pins surrounding the printed circuit board or assembly remaining in the fully extended positions; and using an actuator, located along the main housing, to lock the plurality of support pins in a locked position, thereby holding the printed circuit board or assembly in place and allowing transport of the printed circuit board or assembly.

15. The method of claim 14, wherein the main housing has a top plate and a bottom plate that is spaced from the top plate, wherein the top plate has a plurality of first through holes formed therein and the UPPS further includes an intermediate plate that is disposed between and can move laterally relative to the top plate and the bottom plate; the intermediate plate having a plurality of second through holes formed therein, the first and second through holes being axially aligned relative to one another; and wherein each support pin has an elongated shaft and a head that is enlarged relative to the elongated shaft, the elongated shaft passing through one first through hole, while the head being sized only for reception in the second through hole aligned with the one first through hole but not the aligned first through hole.

16. The method of claim 15, wherein the UPPS is assembled by first aligning the top plate and the intermediate plate such that the first and second through holes align and then inserting the support pins into the aligned first and second through holes and then attaching the bottom plate to the top plate, with the actuator being disposed between the top plate and the bottom plate.

17. The method of claim 14, wherein the step of using the actuator comprises the step of moving the actuator to apply a shear force to the intermediate plate resulting in lateral movement of the intermediate plate causing the plurality of support pins to be set so that the plurality of support pins protrude select distances from an outer surface of the top plate allowing for a set surface contour of the plurality of support pins.

18. The method of claim 14, wherein the actuator comprises a CAM knob that is rotatably coupled to the main housing and configured to drive the intermediate plate in a lateral direction, wherein the CAM knob has an eccentric body that includes an off-centered mounting hole such that rotation of the CAM knob about the off-centered mounting hole has a varying radius with respect to radial orientation.

19. A universal pin production support (UPPS) that acts as a resettable surface mount carrier for fixing and supporting a printed circuit board comprising:
a main housing having a top plate and a bottom plate that is spaced from the top plate,
wherein the top plate has a plurality of first through holes formed therein;
an intermediate plate that is disposed between and can move laterally relative to the top plate and the bottom plate; the intermediate plate having a plurality of second through holes formed therein, the first and second through holes being axially aligned relative to one another, wherein a diameter of the second through hole is greater than a diameter of the first through hole;
a plurality of support pins, each support pin having an elongated shaft and a head that is enlarged relative to the elongated shaft, the elongated shaft passing through one first through hole, while the head being sized only for reception in the second through hole aligned with the one first through hole but not the aligned first through hole;
an eccentrically mounted actuator for applying a shear force to the intermediate plate resulting in lateral movement of the intermediate plate and contact between the intermediate plate and the plurality of support pins causing the plurality of support pins to be set so that the plurality of support pins protrude select distances from an outer surface of the top plate allowing for a set surface contour of the plurality of support pins, wherein the actuator comprises a CAM knob that is rotatably coupled to the main housing and configured to drive the intermediate plate in a lateral direction, wherein the CAM knob has an eccentric body that includes an off-centered mounting hole such that rotation of the CAM knob about the off-centered mounting hole has a varying radius with respect to radial orientation.
